(19) United States
(12) Patent Application Publication
(10) Pub. No.: US 2013/0015469 A1
(43) Pub. Date: Jan. 17, 2013

(54) METHOD FOR MANUFACTURING DIODE, AND DIODE

(71) Applicant: Hideki Hayashi, Osaka-shi (JP)

(72) Inventor: Hideki Hayashi, Osaka-shi (JP)

(73) Assignee: Sumitomo Electric Industries, Ltd., Osaka-shi (JP)

(21) Appl. No.: 13/544,249

(22) Filed: Jul. 9, 2012

Related U.S. Application Data
(60) Provisional application No. 61/507,861, filed on Jul. 14, 2011.

(30) Foreign Application Priority Data
Jul. 14, 2011 (JP) 2011-155286

(51) Int. Cl. H01L 21/20; H01L 29/872; H01L 29/12

(52) U.S. Cl. 257/77; 438/105; 257/E29.338; 257/E29.068; 257/E21.09

(57) ABSTRACT

A semiconductor substrate having a first side and a second side made of single crystal silicon carbide is prepared. A mask layer having a plurality of openings and made of silicon oxide is formed on the second side. The plurality of openings expose a plurality of regions included in the second side, respectively. A plurality of diamond portions are formed by epitaxial growth on the plurality of regions, respectively. The epitaxial growth is stopped before the plurality of diamond portions come into contact with each other. A Schottky electrode is formed on each of the plurality of diamond portions. An ohmic electrode is formed on the first side.

### BACKGROUND OF THE INVENTION

1. Field of the Invention

The present invention relates to a diode and a method for manufacturing the same, and in particular to a diode having a Schottky electrode and a method for manufacturing the same.

2. Description of the Background Art

A pn diode using silicon (Si) has been conventionally adopted as a diode for a power semiconductor. The diode has a relatively low breakdown voltage of about several tens of volts. Thus, a Schottky barrier diode using silicon carbide (SiC) or gallium nitride (GaN) is under consideration as a diode having a higher breakdown voltage. Although the diode has a breakdown voltage more than 1000 V, it has a relatively large leakage current. Therefore, using diamond as a semiconductor material for the Schottky barrier diode is under consideration. There have been proposed methods for suppressing leakage current when diamond is used. For example, according to Japanese Patent Laying-Open No. 2007-095975, a diamond thin film is inspected beforehand for a crystal defect such as an abnormal growth particle or a growth hill, and a pattern for a Schottky electrode is formed to avoid the defect.

Since the technique described in the above publication requires formation of the pattern in accordance with the result of the inspection for the defect, it has been difficult to apply the technique to mass production. Therefore, there has been a demand for another method capable of suppressing leakage current.

### SUMMARY OF THE INVENTION

The present invention has been made in view of the aforementioned problem, and one object of the present invention is to provide a method for manufacturing a diode capable of suppressing leakage current, and the diode.

A method for manufacturing a diode in accordance with the present invention has the steps of: preparing a semiconductor substrate having a first side and a second side located opposite to the first side and made of single crystal silicon carbide, and having one conductivity type; forming a mask layer having a plurality of openings and made of silicon oxide on the second side, the plurality of openings exposing a plurality of regions included in the second side, respectively; forming a plurality of diamond portions having the one conductivity type and each having a single crystal structure, by epitaxial growth on the plurality of regions, respectively, the epitaxial growth being stopped before the plurality of diamond portions come into contact with each other; forming a Schottky electrode on each of the plurality of diamond portions; and forming an ohmic electrode on the first side.

According to the manufacturing method described above, on the semiconductor substrate, the plurality of diamond portions constituting the diode are grown so as not to come into contact with each other. Thereby, leakage current due to a crystal defect can be suppressed, when compared with a case where a single diamond portion is grown, while ensuring a cross sectional area which defines a current density of the diode.

Preferably, in the manufacturing method described above, the Schottky electrode has a plurality of electrode portions located on the plurality of diamond portions, respectively, and separated from each other. Thereby, the Schottky electrode can be selectively provided at the most appropriate position in each diamond portion.

Preferably, in the manufacturing method described above, a wire electrically connecting the plurality of electrode portions with each other is formed. Thereby, currents of the plurality of electrode portions can be collected into a current of one wire.

Preferably, in the manufacturing method described above, the step of forming the plurality of diamond portions is performed such that a portion of each of the plurality of diamond portions which is in contact with the Schottky electrode has an impurity concentration lower than an impurity concentration of a portion of each of the plurality of diamond portions which is in contact with the semiconductor substrate. Thereby, a breakdown voltage can be increased by further extending a depletion layer in an OFF state, while suppressing an ON resistance due to the entire diamond portions.

Preferably, in the manufacturing method described above, the step of forming the plurality of diamond portions is performed such that each of the plurality of diamond portions has a surface parallel to the second side. In the step of forming the Schottky electrode, the Schottky electrode is formed on the surface. Thereby, the Schottky electrode parallel to the second side can be formed.

Preferably, in the manufacturing method described above, the step of forming the plurality of diamond portions includes the step of planarizing the diamond portions when the diamond portions are at least partially formed. Thereby, the surface parallel to the second side can be formed in each of the plurality of diamond portions. Thus, by forming the Schottky electrode on the surface, the Schottky electrode can be made parallel to the second side.

A diode in accordance with the present invention has a semiconductor substrate, a mask layer, a plurality of diamond portions, a Schottky electrode, and an ohmic electrode. The semiconductor substrate has a first side and a second side located opposite to the first side and made of single crystal silicon carbide, and has one conductivity type. The mask layer is provided on the second side, has a plurality of openings, and is made of silicon oxide. The plurality of openings expose a plurality of regions included in the second side, respectively. The plurality of diamond portions are provided on the plurality of regions, respectively, have the one conductivity type, each have a single crystal structure, and are separated from each other. The Schottky electrode is provided on each of the plurality of diamond portions. The ohmic electrode is provided on the first side.

According to the diode described above, the plurality of diamond portions which are not in contact with each other are provided. By using the plurality of diamond portions as described above, a crystal defect can be readily suppressed, when compared with a case where a single diamond portion having an area corresponding to the total area of the plurality of diamond portions is used. Thereby, leakage current due to a crystal defect can be suppressed, while ensuring the cross sectional area which defines the current density of the diode.

Preferably, in the diode described above, the Schottky electrode has a plurality of electrode portions located on the plurality of diamond portions, respectively, and separated from each other. Thereby, the Schottky electrode can be selectively provided at the most appropriate position in each diamond portion.

Preferably, in the diode described above, the diode has a wire electrically connecting the plurality of electrode portions with each other. Thereby, currents of the plurality of electrode portions can be collected into a current of one wire.

Preferably, in the diode described above, a portion of each of the plurality of diamond portions which is in contact with the Schottky electrode has an impurity concentration lower than an impurity concentration of a portion of each of the plurality of diamond portions which is in contact with the semiconductor substrate. Thereby, a breakdown voltage can be increased by further extending a depletion layer in an OFF state, while suppressing an ON resistance due to the entire diamond portions.

Preferably, in the diode described above, each of the plurality of diamond portions has a surface parallel to the second side. The Schottky electrode is provided on the surface. Thereby, the Schottky electrode parallel to the second side can be formed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a view schematically showing a configuration of a diode in one embodiment of the present invention, which is a partial cross sectional view corresponding to a line IA-IA in FIG. 1B.

FIG. 1B is a view schematically showing the configuration of the diode in one embodiment of the present invention, which is a partial plan view schematically showing an internal configuration of the diode of FIG. 1A.

FIG. 2A is a flowchart schematically illustrating a method for manufacturing a diode in one embodiment of the present invention.

FIG. 2B is a flowchart illustrating the step of forming a plurality of diamond portions in the flowchart of FIG. 2A, in more detail.

FIG. 3A is a view schematically showing a first step of the method for manufacturing a diode in one embodiment of the present invention, which is a partial cross sectional view corresponding to a line IIIA-IIIA in FIG. 3B.

FIG. 3B is a partial plan view schematically showing the first step of the method for manufacturing a diode in one embodiment of the present invention.

FIG. 4A is a view schematically showing a second step of the method for manufacturing a diode in one embodiment of the present invention, which is a partial cross sectional view corresponding to a line IVA-IVA in FIG. 4B.

FIG. 4B is a partial plan view schematically showing the second step of the method for manufacturing a diode in one embodiment of the present invention.

FIG. 5A is a view schematically showing a third step of the method for manufacturing a diode in one embodiment of the present invention, which is a partial cross sectional view corresponding to a line VA-VA in FIG. 5B.

FIG. 5B is a partial plan view schematically showing the third step of the method for manufacturing a diode in one embodiment of the present invention.

FIG. 6A is a view schematically showing a fourth step of the method for manufacturing a diode in one embodiment of the present invention, which is a partial cross sectional view corresponding to a line VIA-VIA in FIG. 6B.

FIG. 6B is a partial plan view schematically showing the fourth step of the method for manufacturing a diode in one embodiment of the present invention.

FIG. 7A is a view schematically showing a fifth step of the method for manufacturing a diode in one embodiment of the present invention, which is a partial cross sectional view corresponding to a line VIIA-VIIA in FIG. 7B.

FIG. 7B is a partial plan view schematically showing the fifth step of the method for manufacturing a diode in one embodiment of the present invention.

### DESCRIPTION OF THE PREFERRED EMBODIMENTS

Hereinafter, an embodiment of the present invention will be described with reference to the drawings.

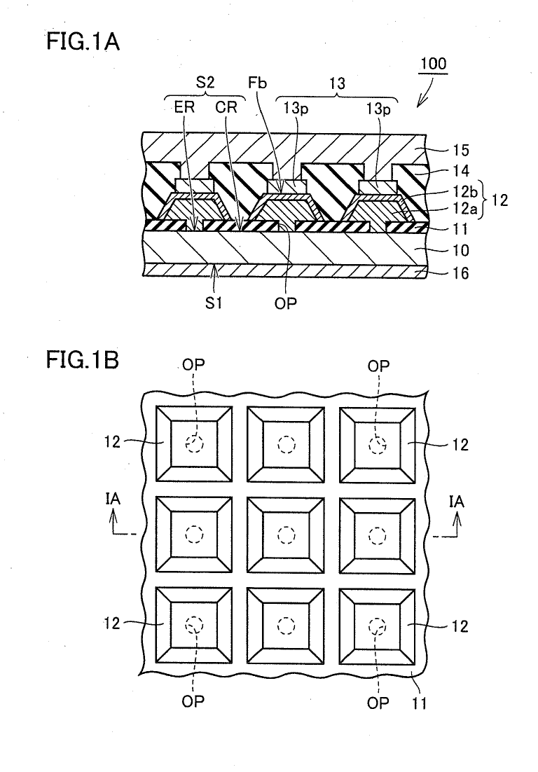

As shown in FIGS. 1A and 1B, a diode 100 in the present embodiment has a silicon carbide substrate 10 (semiconductor substrate), a mask layer 11, a plurality of diamond portions 12, a Schottky electrode 13, an interlayer insulating film 14, a wire 15, and an ohmic electrode 16.

Silicon carbide substrate 10 has a back side S1 (first side) and an upper side S2 (second side) located opposite to back side S1. Further, silicon carbide substrate 10 is made of single crystal silicon carbide (SiC). Accordingly, upper side S2 is also made of single crystal silicon carbide. The silicon carbide preferably has a cubic crystal structure (3C type), and in this case, upper side S2 preferably has a plane orientation of a (100) plane. Further, silicon carbide substrate 10 has p type (one conductivity type). As an impurity for imparting p type, for example, aluminum (Al) or boron (B) is adopted.

Mask layer 11 is provided on upper side S2. Mask layer 11 is made of silicon oxide (SiO₂). Mask layer 11 has a plurality of openings OP. The plurality of openings OP expose a plurality of regions ER included in upper side S2 of silicon carbide substrate 10, respectively. Each opening OP has, for example, a circular shape. Each opening OP has a diameter of, for example, several micrometers to several tens of micrometers. Preferably, openings OP are arranged at regular intervals in a first direction (for example, a transverse direction in FIGS. 1A and 1B), and more preferably arranged at regular intervals also in a second direction crossing the first direction (for example, a longitudinal direction in FIGS. 1A and 1B). Preferably, the first and second directions are perpendicular to each other. The interval is, for example, about 10 to 100 μm.

The plurality of diamond portions 12 are provided on the plurality of regions ER, respectively. The plurality of regions ER are separated from each other. Each diamond portion 12 has the same conductivity type as that of the semiconductor substrate, and in the present embodiment, it has p type. Each diamond portion has a single crystal structure. As an impurity for imparting p type, for example, boron (B) is adopted.

Specifically, each diamond portion 12 has a p⁺ portion 12a and a p⁻ portion 12b. P⁺ portion 12a is located on silicon carbide substrate 10 provided with mask layer 11. P⁻ portion 12b is located on p⁺ portion 12a. P⁻ portion 12b has an impurity concentration lower than an impurity concentration of p⁺ portion 12a. P⁻ portion 12b of each diamond portion 12 has a surface Fb parallel to upper side S2.

Schottky electrode 13 is provided on each of the plurality of diamond portions 12. Specifically, Schottky electrode 13 has a plurality of electrode portions 13p separated from each other, which are located on the plurality of diamond portions 12, respectively. In the present embodiment, each electrode portion 13p is provided on surface Fb of diamond portion 12. Accordingly, of p⁺ portion 12a and p⁻ portion 12b, each electrode portion 13p is in contact with p⁻ portion 12b, and thereby a portion of each of the plurality of diamond portions 12 which is in contact with Schottky electrode 13 has an impurity concentration lower than an impurity concentration of a portion of each of the plurality of diamond portions 12 which is in contact with silicon carbide substrate 10. As a material for Schottky electrode 13, for example, platinum (Pt), gold (Au), aluminum (Al), molybdenum (Mo), or ruthenium (Ru) is adopted.

Wire 15 electrically connects the plurality of electrode portions 13p with each other. The interlayer insulating film 14 provides insulation between wire 15 and diamond portions 12. Ohmic electrode 16 is provided on back side S1 of silicon carbide substrate 10. As a material for ohmic electrode 16, for example, titanium (Ti) is adopted.

Next, a method for manufacturing diode 100 will be described.

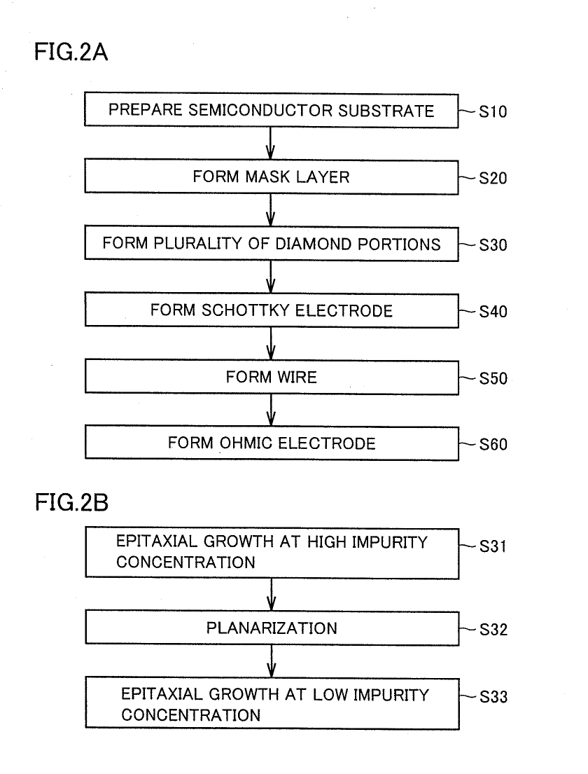

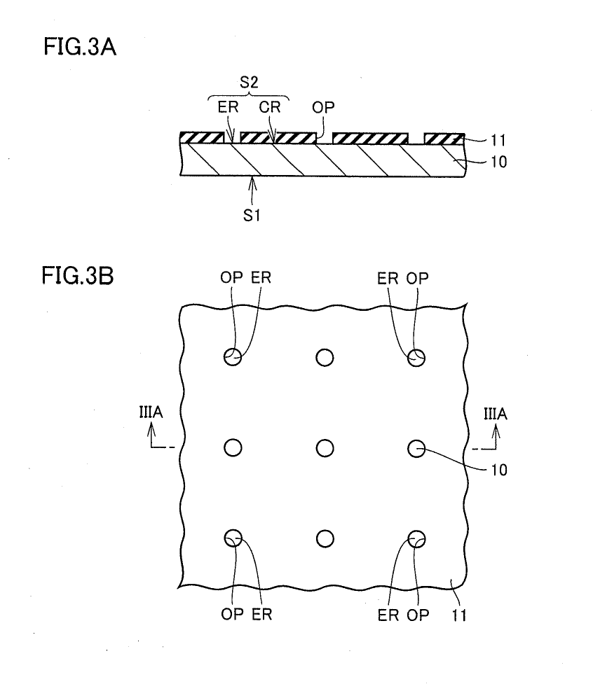

Firstly, as shown in FIGS. 3A and 3B, silicon carbide substrate 10 is initially prepared (FIG. 2A: step S10). Then, mask layer 11 having the plurality of openings OP and made of silicon oxide is formed on upper side S2 of silicon carbide substrate 10 (FIG. 2A: step S20). The plurality of openings OP expose the plurality of regions ER included in upper side S2 of silicon carbide substrate 10, respectively.

Subsequently, step S30 (FIG. 2A) of forming the plurality of diamond portions 12 (FIGS. 1A and 1B) is performed through steps S31 to S33 (FIG. 2B) described below.

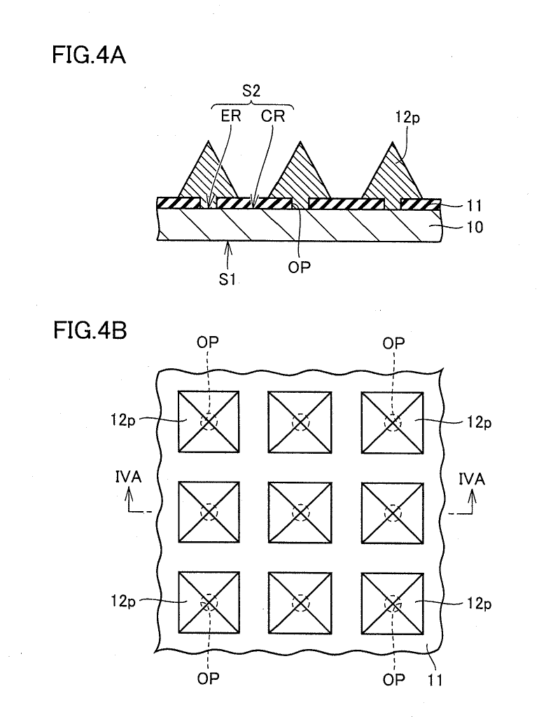

As shown in FIGS. 4A and 4B, a plurality of diamond portions 12p having a high impurity concentration corresponding to the impurity concentration of p⁺ portion 12a and each having a single crystal structure are formed by epitaxial growth on the plurality of regions ER, respectively (FIG. 2B: step S31). The growth can be performed, for example, by a plasma CVD (Chemical Vapor Deposition) method. Further, the growth is stopped before the plurality of diamond portions 12p come into contact with each other. As a result, firstly, growth such as filling opening OP occurs, followed by growth such as extending from opening OP in the transverse direction (in-plane direction in FIG. 4B) when viewed in a plan view. Consequently, diamond portion 12p has a shape of a quadrangular pyramid on mask layer 11.

Examples of conditions for the CVD method include: a growth temperature of about 800 to 950° C.; a process gas as a mixed gas which contains methane gas (CH₄) as a source gas, diborane (B₂H₆) as a doping gas, and hydrogen (H₂) gas as a carrier gas; a methane gas concentration of 0.2 to 8 volume % in the process gas; and a pressure of about 13 kPa. In the growth, carbon (C) atoms are not substantially deposited on mask layer 11 made of silicon oxide, but are selectively deposited on regions ER made of silicon carbide substrate 10.

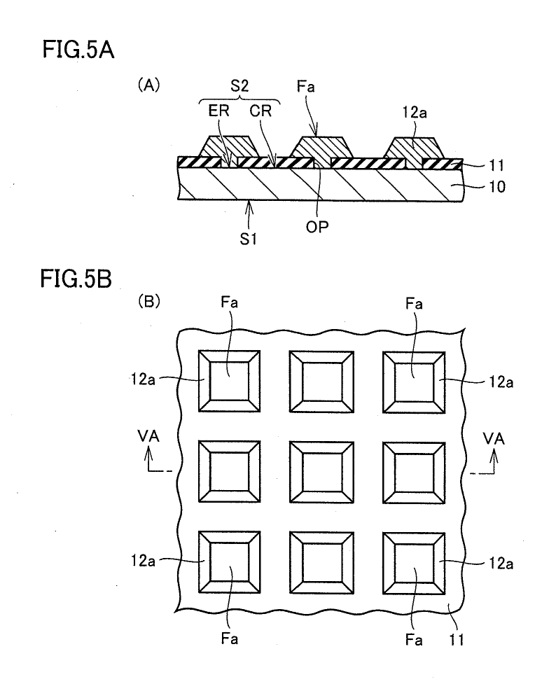

Next, each diamond portion 12p is planarized by polishing (FIG. 2B: step S32). Thereby, as shown in FIGS. 5A and 5B, a plurality of p⁺ portions 12a each having a surface Fa are formed. Each surface Fa is parallel to upper side S2 of silicon carbide substrate 10.

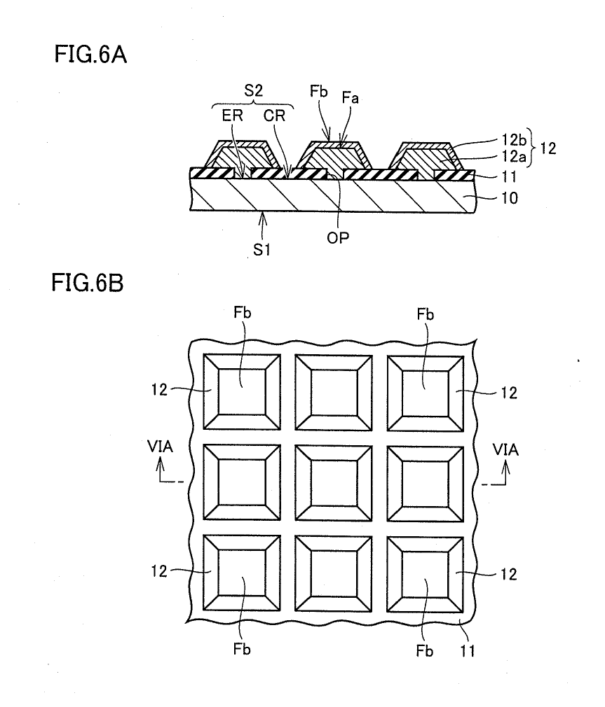

Subsequently, as shown in FIGS. 6A and 6B, epitaxial growth having an impurity concentration lower than that of the above epitaxial growth is performed on each of the plurality of p⁺ portions 12a. Thereby, a plurality of p⁻ portions 12b are formed (FIG. 2B: step S33). In the growth, carbon (C) atoms are not substantially deposited on mask layer 11 made of silicon oxide, but are selectively deposited on p⁺ portions 12a made of diamond. As a result, p⁻ portions 12b are formed to selectively cover p⁺ portions 12a. Further, surface Fb made of p⁻ portion 12b is formed on surface Fa of each p⁺ portion 12a. As with surface Fa, surface Fb is parallel to upper side S2 of silicon carbide substrate 10. The epitaxial growth is stopped before the plurality of p⁻ portions 12b come into contact with each other. In other words, the epitaxial growth is stopped before the plurality of diamond portions 12 come into contact with each other.

As described above, step S30 (FIG. 2A) of forming the plurality of diamond portions 12 is performed.

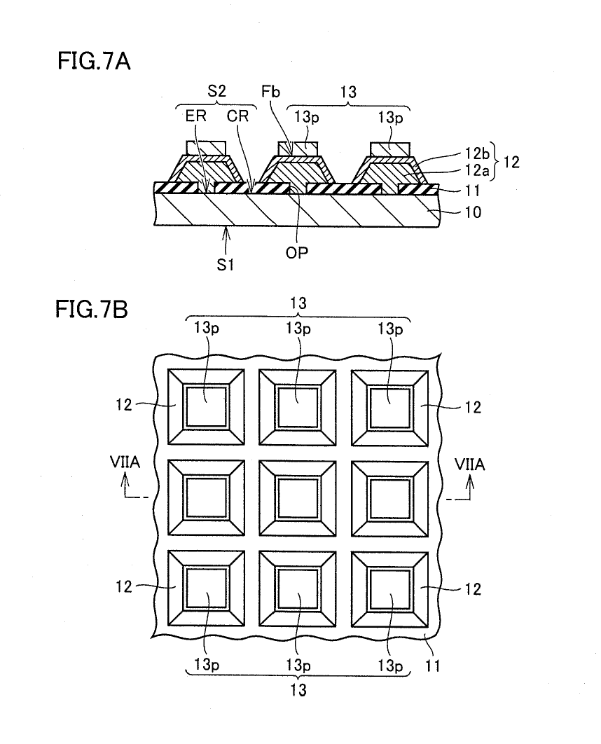

Next, as shown in FIGS. 7A and 7B, Schottky electrode 13 is formed (FIG. 2A: step S40). Namely, as Schottky electrode 13, the plurality of electrode portions 13p separated from each other are formed on the plurality of diamond portions 12, respectively. Specifically, formation of a thin film which will serve as Schottky electrode 13 and patterning using photolithography are performed. The patterning is performed such that each electrode portion 13p is selectively located on surface Fb of p⁻ portion 12b of diamond portion 12.

Subsequently, as shown in FIGS. 1A and 1B, interlayer insulating film 14 and wire 15 are formed (FIG. 2A: step S50). Specifically, formation of a thin film which will serve as interlayer insulating film 14, formation of contact holes exposing the plurality of electrode portions 13p, respectively, and formation of wire 15 electrically connecting the plurality of electrode portions 13p with each other through the contact holes are performed. Further, ohmic electrode 16 is formed on back side S1 (FIG. 2A: step S60). Thereafter, dicing of silicon carbide substrate 10 is performed as necessary, and thereby diode 100 is obtained.

According to the present embodiment, on silicon carbide substrate 10, the plurality of diamond portions 12 constituting diode 100 are grown so as not to come into contact with each other. Thereby, leakage current due to a crystal defect can be suppressed, when compared with a case where a single diamond portion 12 is grown, while ensuring a cross sectional area which defines a current density of diode 100.

In other words, the plurality of diamond portions 12 which are not in contact with each other are provided in diode 100. By using the plurality of diamond portions 12 as described above, a crystal defect can be readily suppressed, when compared with a case where a single diamond portion 12 having an area corresponding to the total area of the plurality of diamond portions 12 is used. Thereby, leakage current due to a crystal defect can be suppressed, while ensuring the cross sectional area which defines the current density of diode 100.

It is to be noted that, if the plurality of diamond portions 12 continue being grown until diamond portions 12 come into contact with each other, a crystal defect extends from a position of contact, which results in an increase in leakage current of the diode. Further, if mask layer 11 is omitted, one diamond portion having a large area is grown, and a crystal defect is likely to occur in such growth of diamond with a large area.

Further, according to the present embodiment, Schottky electrode 13 has the plurality of electrode portions 13p, and the plurality of electrode portions 13p are located on the plurality of diamond portions 12, respectively, and separated from each other. Thereby, Schottky electrode 13 can be selectively provided at the most appropriate position in each diamond portion 12.

Further, diode 100 has wire 15 electrically connecting the plurality of electrode portions 13p with each other. Thereby, currents of the plurality of electrode portions 13p can be collected into a current of one wire 15.

Further, a portion of each of the plurality of diamond portions 12 which is in contact with Schottky electrode 13 has an impurity concentration lower than an impurity concentration of a portion of each of the plurality of diamond portions 12 which is in contact with silicon carbide substrate 10. Thereby, a breakdown voltage can be increased by further extending a depletion layer in an OFF state, while suppressing an ON resistance due to entire diamond portions 12.

Further, the step of forming the plurality of diamond portions 12 is performed such that each of the plurality of diamond portions 12 has surface Fb (FIGS. 6A and 6B) parallel to upper side S2 of silicon carbide substrate 10. Then, Schottky electrode 13 is formed on surface Fb. Thereby, Schottky electrode 13 parallel to upper side S2 of silicon carbide substrate 10 can be formed.

Further, since surface Fa (FIGS. 5A and 5B) is formed by planarizing diamond portion 12p (FIGS. 4A and 4B), p⁻ portion 12b (FIGS. 6A and 6B) having surface Fb parallel to upper side S2 of silicon carbide substrate 10 can be formed on surface Fa. Thus, by forming Schottky electrode 13 on the surface, Schottky electrode 13 can be made parallel to upper side S2.

Further, each of the plurality of diamond portions 12 has surface Fb parallel to upper side S2, and Schottky electrode 13 is provided on surface Fb. Thereby, Schottky electrode 13 parallel to upper side S2 of silicon carbide substrate 10 can be formed.

Further, as shown in FIG. 6A, p⁻ portion 12b includes a portion with a substantially constant thickness, between surface Fa and surface Fb. By forming Schottky electrode 13 on this portion, the ON resistance and the breakdown voltage of diode 100 are stabilized.

It is to be noted that the semiconductor substrate is not limited to silicon carbide substrate 10 (FIG. 1A), and any one having an upper side made of single crystal silicon carbide can be used. For example, a silicon substrate having a single crystal silicon carbide layer formed thereon may be used.

Further, each diamond portion is not limited to the configuration of diamond portion 12 having p⁺ portion 12a with a high impurity concentration and p⁻ portion 12b with a low impurity concentration (FIG. 1A). It may be configured of one region having a uniform impurity concentration, or may be configured of a region having a continuously varying impurity concentration.

Further, each diamond portion is not limited to the one having surface Fb parallel to the upper side of the semiconductor substrate (FIG. 1A), and, for example, the portion in contact with the Schottky electrode may have a shape of a quadrangular pyramid.

Further, the conductivity type of the semiconductor substrate and the diamond portions is not limited to p type, and may be n type.

Further, by adjusting the conditions for the epitaxial growths of the diamond portions, diamond portions each having the same shape as that of p⁺ portion 12a having surface Fa (FIGS. 5A and 5B) can also be directly grown without being polished, instead of diamond portions 12p each having a shape of a quadrangular pyramid (FIGS. 4A and 4B). The adjustment can be performed, for example, by adjusting the methane gas concentration in the CVD method using methane gas.

Further, step S60 (FIG. 2A) of forming ohmic electrode 16 does not always have to be performed after step S50 of forming wire 15, and may be performed at any timing.

Further, the planar shape of opening OP is not limited to the circular shape (FIG. 1B).

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a diode, comprising the steps of:
preparing a semiconductor substrate having a first side and a second side located opposite to said first side and made of single crystal silicon carbide, and having one conductivity type;
forming a mask layer having a plurality of openings and made of silicon oxide on said second side, said plurality of openings exposing a plurality of regions included in said second side, respectively;
forming a plurality of diamond portions having said one conductivity type and each having a single crystal structure, by epitaxial growth on said plurality of regions, respectively, said epitaxial growth being stopped before said plurality of diamond portions come into contact with each other;
forming a Schottky electrode on each of said plurality of diamond portions; and
forming an ohmic electrode on said first side.

2. The method for manufacturing a diode according to claim 1, wherein said Schottky electrode has a plurality of electrode portions located on said plurality of diamond portions, respectively, and separated from each other.

3. The method for manufacturing a diode according to claim 2, further comprising the step of forming a wire electrically connecting said plurality of electrode portions with each other.

4. The method for manufacturing a diode according to claim 1, wherein the step of forming said plurality of diamond portions is performed such that a portion of each of said plurality of diamond portions which is in contact with said Schottky electrode has an impurity concentration lower than an impurity concentration of a portion of each of said plurality of diamond portions which is in contact with said semiconductor substrate.

5. The method for manufacturing a diode according to claim 1, wherein
the step of forming said plurality of diamond portions is performed such that each of said plurality of diamond portions has a surface parallel to said second side, and
in the step of forming said Schottky electrode, said Schottky electrode is formed on said surface.

6. The method for manufacturing a diode according to claim 5, wherein the step of forming said plurality of diamond portions includes the step of planarizing said diamond portions when said diamond portions are at least partially formed.

7. A diode, comprising:
a semiconductor substrate having a first side and a second side located opposite to said first side and made of single crystal silicon carbide, and having one conductivity type;
a mask layer provided on said second side, having a plurality of openings, and made of silicon oxide, said plurality of openings exposing a plurality of regions included in said second side, respectively;
a plurality of diamond portions provided on said plurality of regions, respectively, having said one conductivity type, each having a single crystal structure, and separated from each other;
a Schottky electrode provided on each of said plurality of diamond portions; and
an ohmic electrode provided on said first side.

8. The diode according to claim 7, wherein said Schottky electrode has a plurality of electrode portions located on said plurality of diamond portions, respectively, and separated from each other.

9. The diode according to claim 8, further comprising a wire electrically connecting said plurality of electrode portions with each other.

10. The diode according to claim 7, wherein a portion of each of said plurality of diamond portions which is in contact with said Schottky electrode has an impurity concentration lower than an impurity concentration of a portion of each of said plurality of diamond portions which is in contact with said semiconductor substrate.

11. The diode according to claim 7, wherein
each of said plurality of diamond portions has a surface parallel to said second side, and
said Schottky electrode is provided on said surface.
